(19) United States
(12) Patent Application Publication
(10) Pub. No.: US 2022/0102238 A1
(43) Pub. Date: Mar. 31, 2022

(54) Electronic Device and Method for Assembling an Electronic Device

(71) Applicant: ZF Friedrichshafen AG, Friedrichshafen (DE)

(72) Inventors: Maximilian Olpp, Horgenzell (DE); Danny Grusser, Tettnang (DE); Boris Heberle, Friedrichshafen (DE)

(21) Appl. No.: 17/420,871

(22) PCT Filed: Dec. 18, 2019
(86) PCT No.: PCT/EP2019/085876

§ 371 Date: Jul. 6, 2021

(30) Foreign Application Priority Data
Jan. 7, 2019 (DE) 10 2019 200 096.7

(51) Int. Cl. H01L 23/367; H01L 23/42

(52) U.S. Cl. CPC H01L 23/3675; H01L 23/42

(57) ABSTRACT

An electronic device includes at least one electronic module (CHIP) arranged on a printed circuit plate (LP) and, on the top side, is connected to a heat sink (HS) in a force-free manner. A method for assembling an electronic device includes assembling a printed circuit plate (LP), which is provided with at least one electronic module (CHIP), with a heat sink (HS) for dissipating heat from the at least one electronic module (CHIP). The connection between the heat sink (HS) and the at least one electronic module (CHIP) is established in a force-free manner.

### CROSS-REFERENCE TO RELATED APPLICATIONS

The present application is related and has right of priority to German Patent Application No. 102019200096.7 filed in the German Patent Office on Jan. 7, 2019 and is a nationalization of PCT/EP2019/085876 filed in the European Patent Office on Dec. 18, 2019, both of which are incorporated by reference in their entirety for all purposes.

### FIELD OF THE INVENTION

The invention relates generally to an electronic device and to a method for assembling an electronic device.

### BACKGROUND

Unexamined patent application DE 10 2015 204 905 A1 discloses an electronic control device with a housing, a circuit carrier with an electronic power component arranged thereon, wherein the circuit carrier and the electronic power component are contacted to the housing by means of a heat transfer medium, wherein the heat of the power component is dissipatable in a manner directed away from the circuit carrier, and wherein the circuit carrier is fixed in the housing by means of the heat transfer medium.

### SUMMARY OF THE INVENTION

The electronic device according to example aspects of the invention and the method according to example aspects of the invention for assembling an electronic device have the advantage over the prior art that the connection between an electronic module on the printed circuit plate and a heat sink is designed in a force-free manner. Therefore, no mechanical requirements need to be placed on the connection between the heat sink and the electronic component. For the rest, the assembly is therefore also simpler and less challenging, since a mechanical load does not need to be absorbed, as described in the prior art.

An electronic device is to be understood, in the present case, for example, as a control device or another electronic circuit, which is installed into a housing or at least has the assembly with a heat sink. In particular, control devices for evaluating sensor signals and generating control signals for vehicle systems are to be understood in this context as electronic devices.

The electronic device includes at least one electronic module. This electronic module is to be understood, for example, to be a processor or a power module that generates heat that must be dissipated in order to maintain an operation of the electronic device and, thereby, of the module. The module is arranged on a printed circuit plate, i.e., for example, soldered or bonded or inserted, and, on the top side, is connected to a heat sink in a force-free manner according to example aspects of the invention.

The printed circuit plate can be a single-layer or multi-layer printed circuit plate, which, in particular, includes the electronic modules on one side, in order to be able to connect them to the heat sink. In addition, the electronic module can be understood to be an area on the printed circuit plate, which is contacted by the heat sink in a force-free manner, in order to dissipate the heat flowing against the area.

The heat sink is a structure made, for example, of aluminum, with material accumulations, which extend to the electronic modules, so that a force-free connection is made possible, for example, by a heat transfer compound. The heat sink is then connected, for example, via a cooling structure to an air flow or liquid flow, which ultimately dissipates the absorbed heat from the heat sink and, thereby, makes the cooling possible.

In addition, the method is provided for assembling an electronic device. Initially, the printed circuit plate is provided with the at least one electronic module and then assembled with the heat sink for dissipating heat. The connection between the heat sink and the at least one electronic module is established in a force-free manner, i.e., the module is not acted upon by force via this connection.

Due to an appropriate geometric measurement of the topography of the printed circuit plate with the at least one electronic module, the heat sink is adapted to the present topography in such a way that a defined air gap exists between the heat sink and the at least one electronic module. The topography of the printed circuit plate is intended to mean the three-dimensional characteristic, and so the heat sink can appropriately adapt to this characteristic.

The air gap is then filled with the thermally conductive material, and so a conduction of heat is established between the heat sink and the at least one electronic module.

In addition, it is provided that the thermally conductive material is a gap filler. A gap filler is a thermally conductive compound, which includes, for example, silver particles and is distinguished by its particular thermal conductivity.

In addition, it is provided that, between the heat sink and the at least one electronic module, the extension in height is addressed with a material accumulation. In the present case, a defined air gap is formed by the preceding measurement of the printed circuit plate having the electronic modules and pairing with a suitable heat sink. The air gap is then filled with the thermally conductive material, and so a conduction of heat is established between the heat sink and the at least one electronic module.

In addition, it is provided that a spacer element is provided between the heat sink and the at least one electronic module, in order to adjust the thickness of the air gap. This spacer element is, for example, bonded, welded, or screwed onto the heat sink and extends in the direction of the electronic module. In the present case as well, the extension in height is addressed by the preceding measurement of the printed circuit plate with the electronic modules.

In addition, it is provided that the method according to example aspects of the invention provides that a thermally conductive material is applied onto the electronic module and, thereafter, the heat sink with the spacer element is built thereon. A gap filler can be advantageously utilized for this purpose.

In addition, it is provided that a section of the heat sink, which is connected to the thermally conductive material, is designed as a cooling structure. The cooling structure can protrude, for example, into a fluid, so that the heat can be transported away by the fluid.

In addition, it is provided that the method includes a spacer between the heat sink and the printed circuit plate, in order to adjust the thickness of the air gap. This spacer is designed in such a way that the air gap has a certain thickness. This requires a measurement of the topography of the printed circuit plate.

According to a further embodiment, which can be utilized in addition or instead, the spacer element is present at the heat sink for the electronic module, which is then connected to the module via the heat transfer compound.

### BRIEF DESCRIPTION OF THE DRAWINGS

Exemplary embodiments of the invention are explained in greater detail in the following description and are represented in the drawings, in which:

FIG. 1 shows a first exemplary embodiment of the electronic device according to the invention;

FIG. 2 shows a second exemplary embodiment of the electronic device according to the invention;

FIG. 3 shows a third exemplary embodiment of the electronic device according to the invention; and

FIG. 4 shows a flowchart of the method according to example aspects of the invention.

### DETAILED DESCRIPTION

Reference will now be made to embodiments of the invention, one or more examples of which are shown in the drawings. Each embodiment is provided by way of explanation of the invention, and not as a limitation of the invention. For example, features illustrated or described as part of one embodiment can be combined with another embodiment to yield still another embodiment. It is intended that the present invention include these and other modifications and variations to the embodiments described herein.

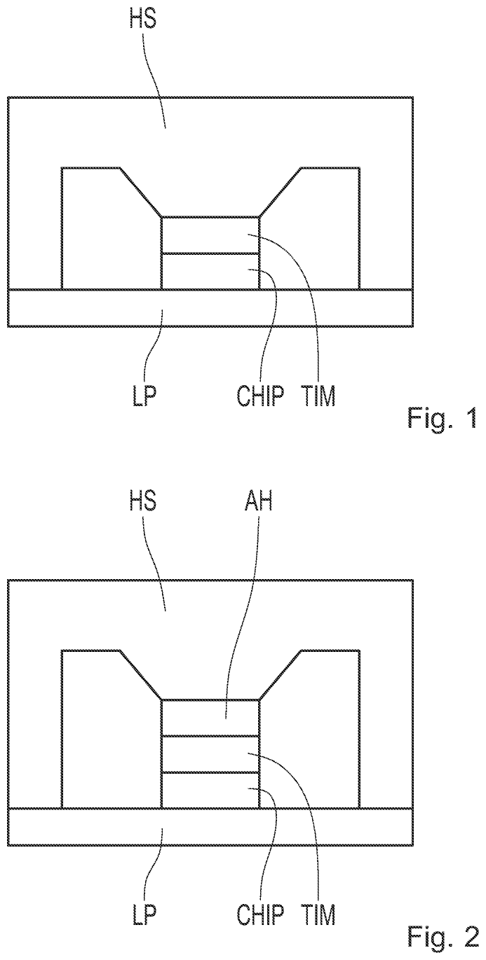

FIG. 1 shows a first exemplary embodiment of the electronic device according to the invention. An electronic module CHIP is arranged on the printed circuit plate LP. Arranged on the electronic module CHIP is a heat transfer compound TIM, followed by a heat sink HS. The heat sink HS also rests against the printed circuit plate LP at at least two points. Initially, the topography of the printed circuit plate LP with the electronic modules is ascertained, and so the heat sink HS can be appropriately adapted thereto. This can take place by machining the heat sink HS. Subsequently, the heat transfer compound TIM is applied onto the electronic module CHIP, since the air gap between the heat sink HS and the electronic module CHIP is known. The heat transfer compound TIM is therefore applied in an appropriate thickness. Therefore, a force-free, thermally conductive connection is established between the electronic module CHIP and the heat sink HS.

FIG. 2 shows a second exemplary embodiment of the electronic device according to the invention. The heat sink HS is applied onto the printed circuit plate LP. In addition, the electronic module CHIP is arranged on the printed circuit plate LP, and the thermally conductive material TIM is applied onto the electronic module CHIP. A spacer AH is located on the thermally conductive material TIM and is fixedly connected to the heat sink HS. The thickness of the spacer AH is adjusted according to the measurement of the printed circuit plate LP with the electronic modules located thereon.

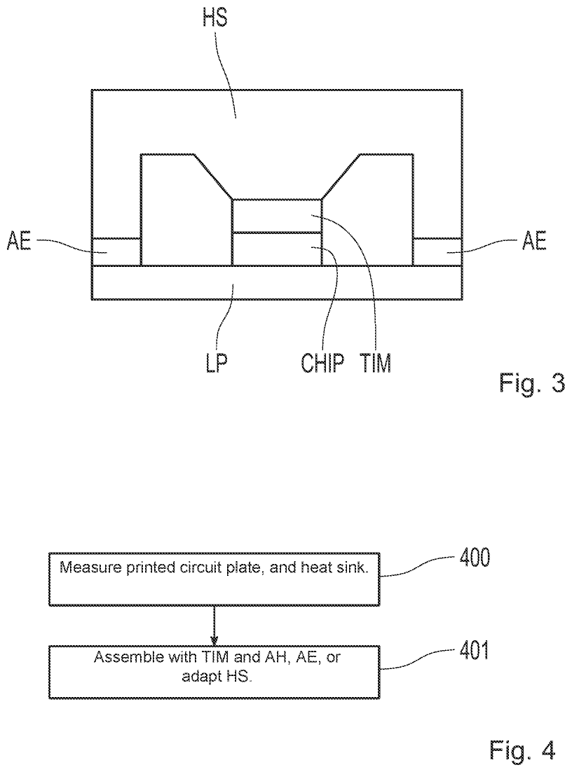

FIG. 3 shows the third exemplary embodiment of the electronic device according to the invention. The heat sink HS is applied onto the printed circuit plate LP via spacer elements AE. In addition, for example, a single electronic module CHIP is located on the printed circuit plate LP. The thermally conductive material TIM is applied between the electronic module CHIP and the heat sink HS. The spacer elements AE are similar in their thickness, and so the air gap between the electronic module CHIP and the heat sink HS is appropriately set.

FIG. 4 shows the manufacturing process for assembling the electronic device. At method step 400, the printed circuit plate LP is measured, either with a laser measurement or with a tracer, in order to ascertain a three-dimensional map of the printed circuit plate. Subsequent thereto, the heat sink HS is designed and/or the spacer elements AE or the spacer H or the heat sink HS. Next, the assembly takes place, in that the thermally conductive material TIM is applied onto the electronic component or components CHIP, in order to fill the air gap between the cooling structure and the electronic module CHIP. This takes place in method step 401.

Modifications and variations can be made to the embodiments illustrated or described herein without departing from the scope and spirit of the invention as set forth in the appended claims. In the claims, reference characters corresponding to elements recited in the detailed description and the drawings may be recited. Such reference characters are enclosed within parentheses and are provided as an aid for reference to example embodiments described in the detailed description and the drawings. Such reference characters are provided for convenience only and have no effect on the scope of the claims. In particular, such reference characters are not intended to limit the claims to the particular example embodiments described in the detailed description and the drawings.

### REFERENCE CHARACTERS

HS heat sink
TIM thermally conductive material
CHIP electronic module
LP printed circuit plate
AH spacer
AE spacer element
400, 401 method steps

1-12: (canceled)

13. An electronic device, comprising
a printed circuit board (LP);
at least one electronic module (CHIP) arranged on the printed circuit plate (LP); and
a heat sink (HS),
wherein the at least one electronic module (CHIP) is connected to the heat sink (HS) in a force-free manner on a top side of the at least one electronic module (CHIP).

14. The electronic device of claim 13, wherein the heat sink (HS) is arranged such that a gap is defined between the heat sink (HS) and the at least one electronic module (CHIP), and a thermally conductive material (TIM) fills the gap in order to establish a heat conduction path between the heat sink (HS) and the at least one electronic module (CHIP) across the gap.

15. The electronic device of claim 14, wherein the thermally conductive material (TIM) is a gap filler.

16. The electronic device of claim 13, wherein a section of the heat sink (HS) connected to the thermally conductive material (TIM) configured as a cooling structure.

17. The electronic device of claim 16, further comprising at least one spacer (AH) provided between the heat sink (HS) and the printed circuit plate (LP) in order to adjust a thickness of a gap defined between the heat sink (HS) and the at least one electronic module (CHIP).

18. The electronic device of claim 13, further comprising at least one spacer element (AE) provided between the heat sink (HS) and the thermally conductive material (TIM).

19. A method for assembling an electronic device, comprising:
assembling a printed circuit plate (LP), which is provided with at least one electronic module (CHIP), with a heat sink (HS) for dissipating heat from the at least one electronic module (CHIP),
wherein a connection between the heat sink (HS) and the at least one electronic module (CHIP) is established in a force-free manner.

20. The method of claim 19, wherein a gap is defined between the heat sink (HS) and the at least one electronic module (CHIP), the method further comprising utilizing a thermally conductive material (TIM) to establish a heat conduction path between the heat sink (HS) and the at least one electronic module (CHIP) across the gap.

21. The method of claim 20, wherein a gap filler is utilized as the thermally conductive material (TIM).

22. The method of claim 19, wherein a section of the heat sink (HS), which is connected to the thermally conductive material (TIM), is configured as a cooling structure.

23. The method of claim 19, further comprising utilizing at least one spacer (AH) between the heat sink (HS) and the printed circuit plate (LP) to adjust a thickness of a gap between the heat sink (HS) and the at least one electronic module (CHIP).

24. The method of claim 19, further comprising positioning at least one spacer element (AE) between the heat sink (HS) and the thermally conductive material (TIM).
